(19) United States
(12) Patent Application Publication
(10) Pub. No.: US 2025/0351571 A1
(43) Pub. Date: Nov. 13, 2025

(54) SEMICONDUCTOR DEVICES AND METHODS OF MANUFACTURING THE SAME

(71) Applicant: Taiwan Semiconductor Manufacturing Company, Ltd., Hsinchu (TW)

(72) Inventors: Wei-Hsuan Peng, Hsinchu (TW); Wei-Lun Chung, Hsinchu (TW); Anhao Cheng, Hsinchu (TW); Chien-Wei Lee, Hsinchu (TW); Yen-Liang Lin, Hsinchu (TW); Ru-Shang Hsiao, Hsinchu (TW)

(73) Assignee: Taiwan Semiconductor Manufacturing Company, Ltd., Hsinchu (TW)

(21) Appl. No.: 19/273,960

(22) Filed: Jul. 18, 2025

Related U.S. Application Data
(63) Continuation of application No. 18/503,425, filed on Nov. 7, 2023.
(60) Provisional application No. 63/519,410, filed on Aug. 14, 2023.

(51) Int. Cl. H10D 84/85; H10D 84/01; H10D 84/03

(52) U.S. Cl. CPC H10D 84/859; H10D 84/0188; H10D 84/0191; H10D 84/038

(57) ABSTRACT

A semiconductor device includes a first well region laterally separated from a second well region in a substrate, a shallow trench isolation (STI) structure laterally between the first well region and the second well region in the substrate, a first implant region of a dopant type opposite to a dopant type of the first well region in the substrate, disposed vertically lower than the STI structure and laterally between the first well region and a lateral center of the STI structure, and a second implant region of a dopant type opposite to a dopant type of the second well region in the substrate, disposed vertically lower than the STI structure and laterally between the second well region and the lateral center of the STI structure.

### CROSS-REFERENCE TO RELATED APPLICATION

This application is a continuation of U.S. patent application Ser. No. 18/503,425, filed Nov. 7, 2023, which claims the benefit of U.S. Provisional Patent Application No. 63/519,410, filed Aug. 14, 2023, all of which are incorporated herein by reference in their entireties and for all purposes.

### BACKGROUND

The semiconductor industry has experienced rapid growth due to continuous improvements in the integration density of a variety of electronic components (e.g., transistors, diodes, resistors, and capacitors). However, the continued improvement in integration density in semiconductor devices leads to closer well spacing, which may cause increase of leakage current among adjacent well regions where e.g., transistors are formed, thereby reducing quality and productivity of the semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a semiconductor device in accordance with some embodiments.

FIGS. 2A, 2B, 2C, 2D and 2E illustrate cross-sectional views of various semiconductor devices in accordance with some embodiments.

FIGS. 3A, 3B, 3C, 3D and 3E illustrate cross-sectional views of various semiconductor devices in accordance with other embodiments.

FIG. 3F illustrates a doping profile of the semiconductor device as shown in FIG. 3A in accordance with some embodiments.

FIG. 3G illustrates results of a simulation performed on the semiconductor device as shown in FIG. 3A in accordance with some embodiments.

FIGS. 4A and 4B illustrate cross-sectional views of a semiconductor device during various fabrication stages in accordance with some embodiments.

FIGS. 5A and 5B illustrate cross-sectional views of a semiconductor device during various fabrication stages in accordance with other embodiments.

FIG. 6 is a flowchart illustrating a method of manufacturing a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Shallow trench isolations deposited in substrates of semiconductor devices can allow closer well spacing, which however may lead to increase of leakage current among adjacent well regions where e.g., CMOS transistors are formed, thereby severely reducing performance and productivity of semiconductor devices. Thus, it is desirable to reduce well-to-well leakage current among adjacent wells caused by closer well spacing in semiconductor devices.

The present disclosure provides various embodiments of a semiconductor device that includes a STI in a substrate, a first deep implant region of a dopant type opposite to a dopant type of an adjacent first well region and a second deep implant region of a dopant type opposite to a dopant type of an adjacent second well region at both sides of the STI. The first deep implant region is formed vertically lower than the STI structure and laterally between the first well region and a lateral center of the STI structure. The second deep implant region is formed vertically lower than the STI structure and laterally between the second well region and the lateral center of the STI structure. Thus, well-to-well leakage current level in the semiconductor device can be reduced due to the first and the second deep anti-well implant regions, thereby obtaining more compact chip design and more robust chip performance of the semiconductor device.

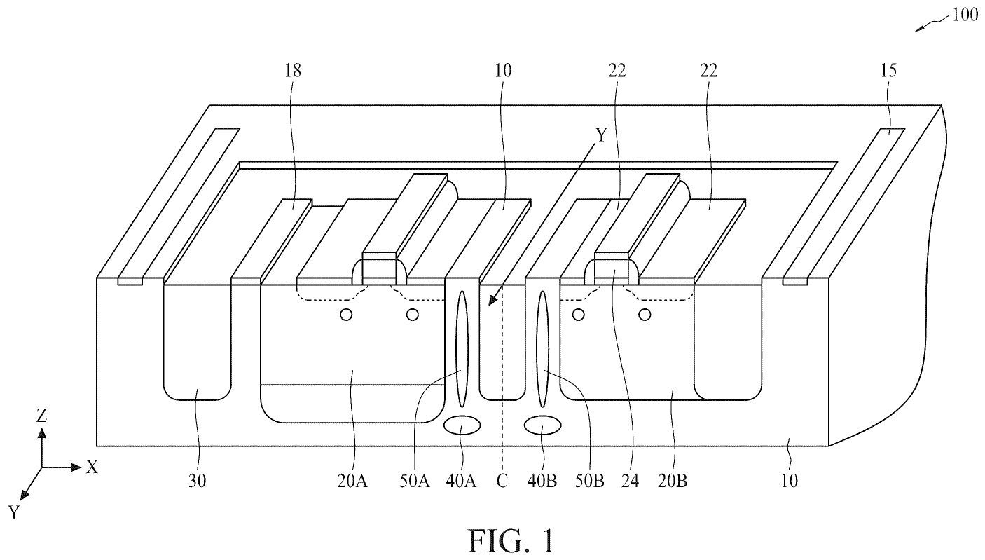

FIG. 1 illustrates a perspective view of a semiconductor device 100 device in accordance with some embodiments. As shown in FIG. 1, the semiconductor device 100 includes a substrate 10, a plurality of implant well regions (such as 20A and 20B) laterally separated from each other in the substrate 10, and an isolation structure 30 laterally separating adjacent implant well regions in the substrate 10. The implant well regions can be N-type and/or P-type. In some embodiments, the isolation structure 30 may include a shallow trench isolation (STI) structure. However, it should be understood that the isolation structure 30 can be implemented as any of various other structures such as, for example, a field oxide or deep trench isolation structure. In the illustrative example of FIG. 1, the STI structure 30 structure surrounds any of the implant well regions 20A and 20B. Other arrangement of the STI structure 30 can also be contemplated, while remaining within the scope of the present disclosure.

In some embodiments, the semiconductor device 100 includes a first deep implant region 40A having a dopant type opposite to a dopant type of the adjacent first well region 20A and disposed vertically lower than the STI structure 30 and laterally between the first well region 20A and a lateral center C of the STI structure 30, and a second deep implant region 40B having a dopant type opposite to a dopant type of the adjacent second well region 20B and disposed vertically lower than the STI structure 30 and laterally between the second well region 20B and the lateral center C of the STI structure 30. The lateral center C of the STI structure 30 is a line that passes through the middle points between the STI boundaries. In some embodiments, the STI structure 30 is in a shape of rectangle. In other embodiments, the STI structure 30 is in a shape of inverted trapezoid.

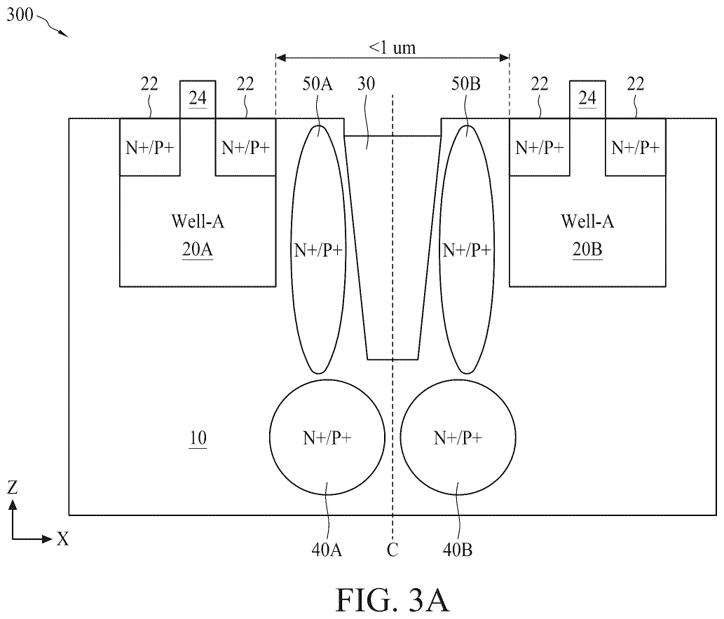

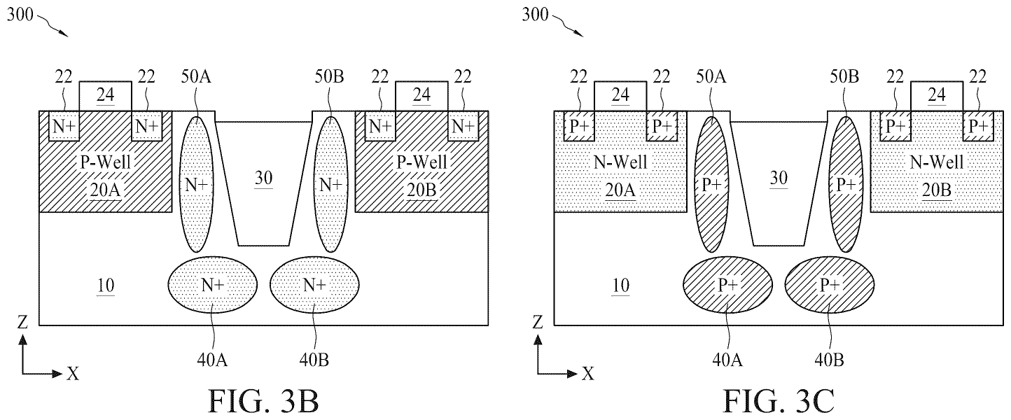

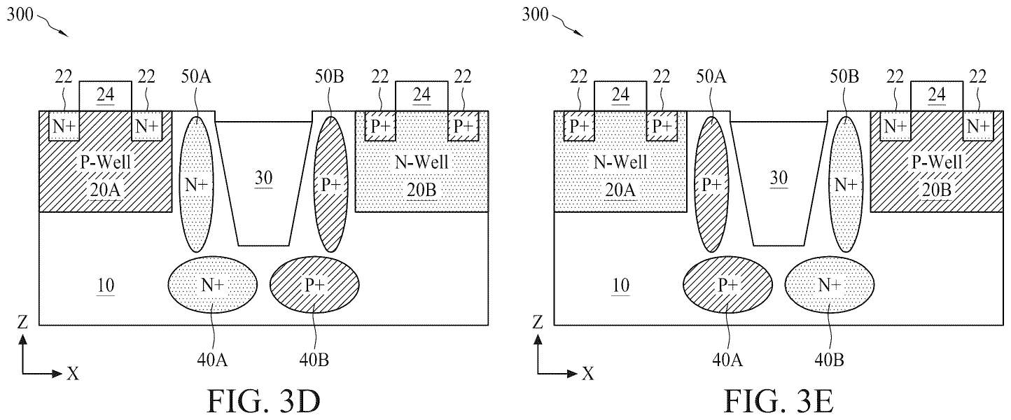

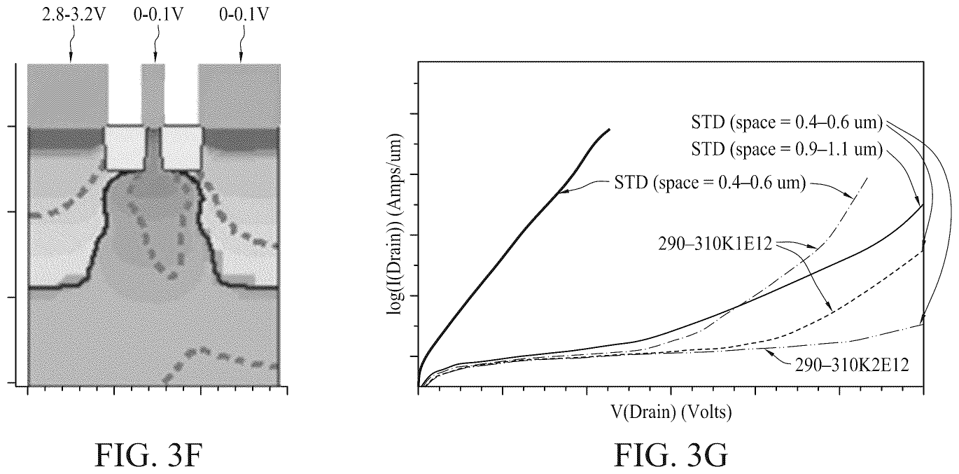

In some embodiments, the semiconductor device 100 includes a first shallow implant region 50A having a dopant type the same as the dopant type of the first deep implant region 40A and disposed vertically over the first deep implant region 40A and laterally between the first well region 20A and the STI structure 30, and a second shallow implant region 50B having a dopant type the same as the dopant type of the second deep implant region 40B and disposed vertically over the second deep implant region 40B and laterally between the second well region 20B and the STI structure 30 (also as shown in FIG. 3A). In some embodiments, lengths of the first deep implant region 40A and the second deep implant region 40B are longer than the lengths of the first well region 20A and the second well region 20B in the Y direction. In some embodiments, lengths of first shallow implant region 50A and the second shallow implant region 50B are longer than the lengths of the first well region 20A and the second well region 20B in the Y direction.

The semiconductor device 100 may further include transistors each including source/drains 22 and a gate structure 24 formed on any of the implant well regions 20A and 20B. Source and drain are used interchangeably in this disclosure. Source/drain region(s) may refer to a source or a drain, individually or collectively dependent upon the context. The semiconductor device 100 may further include a capping layer 15 of e.g., a silicide material partially on a top surface of the substrate 10, and a well capping layer 18 of e.g., a silicide material partially on any of the implant well regions 20A and 20B.

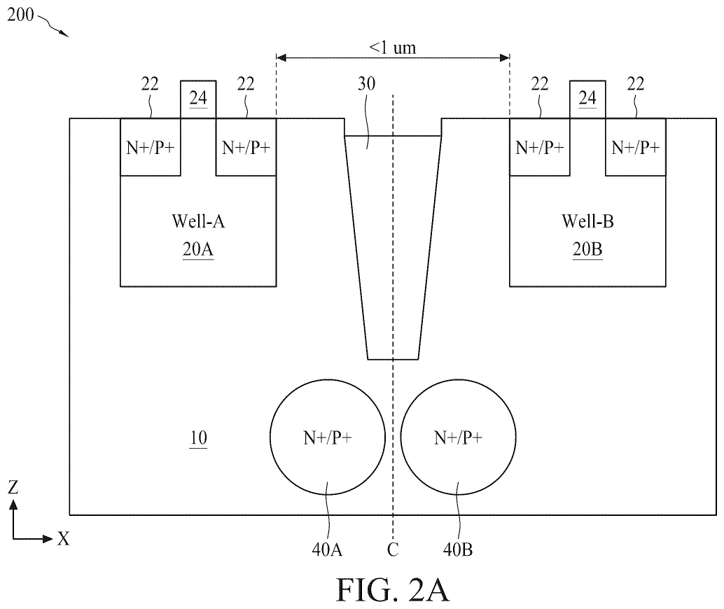

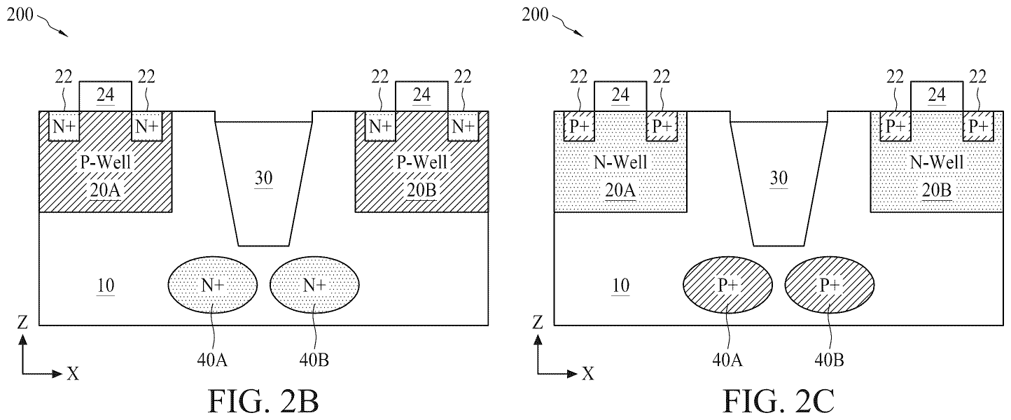

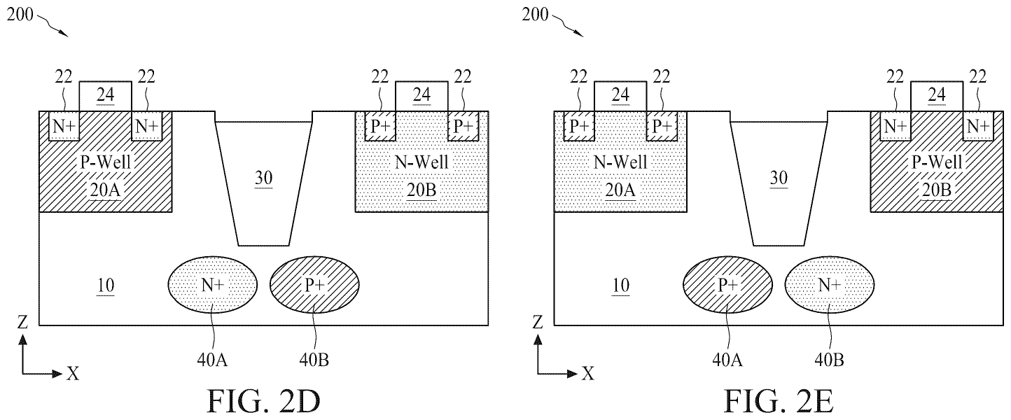

FIGS. 2A, 2B, 2C, 2D and 2E illustrate cross-sectional views of various semiconductor devices 200 in accordance with some embodiments. The semiconductor devices 200 shown in FIGS. 2A-E may each be an implementation of the semiconductor device 100 shown in FIG. 1.

As shown in FIG. 2A, a semiconductor device 200 includes a substrate 10, a first well region 20A laterally separated from a second well region 20B in the substrate 10, a STI structure 30 laterally between the first well region 20A and the second well region 20B in the substrate 10, and a first deep implant region 40A having a dopant type opposite to a dopant type of the first well region 20A and a second deep implant region 40B having a dopant type opposite to a dopant type of the second well region 20B in the substrate 10. In some embodiment, the STI structure 30 is flush with the top surface of the substrate 10 as shown in FIG. 1. In other embodiments, the STI structure 30 is lower than the top surface of the substrate 10 as shown in FIGS. 2A-2E.

The first deep implant region 40A is deeply implanted to be vertically lower than the STI structure 30, and laterally between the first well region 20A and a lateral center C of the STI structure 30 in the substrate 10. The second deep implant region 40B is deeply implanted to be vertically lower than the STI structure 30, and laterally between the second well region 20B and the lateral center C of the STI structure 30 in the substrate 10.

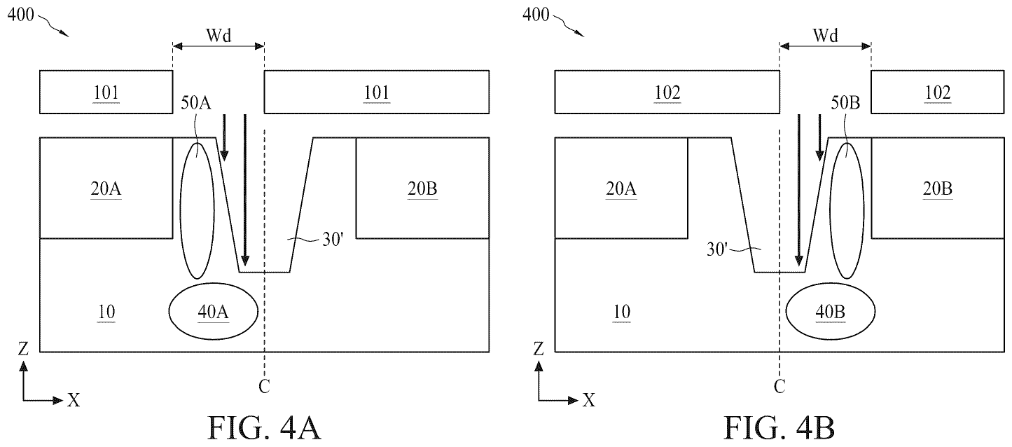

In some embodiments, the STI structure 30 includes an isolation oxide filled or deposited in a STI trench 30′ (as shown in FIGS. 4A and 4B). Various methods of etching and depositing can be used to form and deposit the STI trench 30′ in the substrate 10 of the semiconductor device 200.

In some embodiments, a ratio of a width of the first deep implant region 40A to a width of the STI structure 30 is in a range from 5/100 to 95/100, and a ratio of a width of the second deep implant region 40B to the width of the STI structure 30 is in a range from 5/100 to 95/100. In other embodiments, the ratio of the width of the first deep implant region 40A to the width of the STI structure 30 is in a range from 20/100 to 60/100, and a ratio of the width of the second deep implant region 40B to the width of the STI structure 30 is in a range from 20/100 to 60/100.

In some embodiments, as shown in FIGS. 2B and 2C, the dopant types of the first deep implant region 40A and the second deep implant region 40B are identical. In some embodiments, as shown in FIG. 2B, the dopant types of the first deep implant region 40A and the second deep implant region 40B are N-type. In other embodiments, as shown in FIG. 2C, the dopant types of the first deep implant region 40A and the second deep implant region 40B are P-type.

In other embodiments, as shown in FIGS. 2D and 2E, the dopant types of the first deep implant region 40A and the second deep implant region 40B are opposite to each other. In some embodiments, as shown in FIG. 2D, the dopant type of the first deep implant region 40A is N-type, while the dopant type of the second deep implant region 40B is P-type. In other embodiments, as shown in FIG. 2E, the dopant type of the first deep implant region 40A is P-type, while the dopant type of the second deep implant region 40B is N-type.

Doping conditions include, for example, dopant-types, implanting dosages, implanting energies, and implanting tilt angles of implant materials. In some embodiments, an implant material for P-type implanting is selected from any of B, Ga, In and BF₂, and an implant material for N-type implanting is selected from any of As and P. In some embodiments, implanting dosage of an implant material is in a range from 1 e12 ions/cm² to 5 e12 ions/cm². In some embodiments, implanting energy of an implant material is in a range from 200 KeV to 500 KeV. In some embodiments, implanting tilt angle of an implant material is in a range from 0 degree to 7 degree. The implanting conditions can be independently adjusted to improve segregation quality among adjacent well regions.

According to the present disclosure, deep implant regions 40A and 40B of dopant types opposite to adjacent well regions 20A and 20B and disposed at both sides of the STI structure 30 and lower than the STI structure 30 in the substrate 10 can function as charge barriers between the adjacent well regions, and thus improve segregation among the adjacent implant well regions, thereby reducing well-to-well leakage current level. Thus, performance of the semiconductor device is enhanced.

FIGS. 3A, 3B, 3C, 3D and 3E illustrate cross-sectional views of various semiconductor devices 300 in accordance with some embodiments. The semiconductor devices 300 shown in FIGS. 3A-E may each be an implementation of the semiconductor device 100 shown in FIG. 1.

As shown in FIG. 3A, a semiconductor device 300 includes a substrate 10, a first well region 20A laterally separated from a second well region 20B in the substrate 10, a STI structure 30 laterally between the first well region 20A and the second well region 20B in the substrate 10, a first deep implant region 40A of a first dopant type (e.g., N-type or P-type) opposite to a dopant type (e.g., N-type or P-type) of the first well region 20A disposed vertically lower than the STI structure 30 and laterally between the first well region 20A and a lateral center C of the STI structure 30, and a second deep implant region 40B of a second dopant type (e.g., N-type or P-type) opposite to a dopant type (e.g., N-type or P-type) of the second well region 20B disposed vertically lower than the STI structure 30 and laterally between the second well region 20B and the lateral center C of the STI structure 30 in the substrate 10.

In addition, in some embodiments, the semiconductor device 300 further includes a first shallow implant region 50A having a dopant type identical to the dopant type of the first deep implant region 40A and disposed vertically over the first deep implant region 40A and laterally between the first well region 20A and the STI structure 30, and a second shallow implant region 50B having a dopant type identical to the dopant type of the second deep implant region 40B and disposed vertically over the second deep implant region 40B and laterally between the second well region 40B and the STI structure 30 in the substrate 10.

The shallow implant regions 50A and 50B respectively having opposite dopant types relative to the adjacent well regions 20A and 20B at both sides of the STI structure 30 in the substrate 10 can form additional PN junctions as barriers to further improve segregation between the adjacent well regions 20A and 20B, thereby further reducing well-to-well leakage current level in the semiconductor device 300.

Without segregation provided by the STI structure 30 between the well regions 20A and 20B at a depth lower than the STI structure 30 in the substrate 10, higher dopant concentration is applied in the deep implant regions 40A and 40B than in the shallow implant regions 50A and 50B. In some embodiments, a dopant concentration in the first deep implant region 40A is higher than a dopant concentration in the first shallow implant region 50A, and a dopant concentration in the second deep implant region 40B is higher than a dopant concentration in the second shallow implant region 50B. In some embodiments, dopant concentrations in the deep implant regions 40A and 40B and in the shallow implant regions 50A and 50B increase in the depth direction in the substrate 10 in a gradient way.

As shown in FIGS. 3A, 3B, 3C, 3D and 3E, the first deep implant region 40A and the first shallow implant region 50A have the same dopant type (e.g., N type) that is opposite to a dopant type (e.g., P-type) of the adjacent first well region 20A, and the second deep implant region 40B and the second shallow implant region 50B have the same dopant type (e.g., P type) that is opposite to a dopant type (e.g., N-type) of the adjacent second well region 20B.

As shown in FIGS. 3B and 3C, in some embodiments, the dopant type of the first deep implant region 40A and the first shallow implant region 50A is the same as the dopant type of the second deep implant region 40B and the second shallow implant region 50B. As shown in FIG. 3B, in some embodiments, the dopant type of the first deep implant region 40A and the first shallow implant region 50A as well as the dopant type of the second deep implant region 40B and the second shallow implant region 50B are all N type. As shown in FIG. 3C, in other embodiments, the dopant type of the first deep implant region 40A and the first shallow implant region 50A as well as the dopant type of the second deep implant region 40B and the second shallow implant region 50B are all P type.

As shown in FIGS. 3D and 3E, in other embodiments, the dopant type of the first deep implant region 40A and the first shallow implant region 50A is opposite to the dopant type of the second deep implant region 40B and the second shallow implant region 50B. As shown in FIG. 3D, in some embodiments, the dopant type of the first deep implant region 40A and the first shallow implant region 50A is N-type, while the dopant type of the second deep implant region 40B and the second shallow implant region 50B is P-type. As shown in FIG. 3E, in other embodiments, the dopant type of the first deep implant region 40A and the first shallow implant region 50A is P-type, while the dopant type of the second deep implant region 40B and the second shallow implant region 50B is N-type.

In some embodiments, the semiconductor device 300 further includes a first planar CMOS transistor formed in the first well region 20A and a second planar CMOS transistor formed in the second well region 20B. In some embodiments, the first and the second planar MOSFET transistors each includes source/drains 22 and a gate structure 24.

Doping conditions as mentioned above for doping deep implant regions of semiconductor devices 200 as shown in FIGS. 2A, 2B, 2C, 2D and 2E also apply to doping deep implant regions as well as shallow implant regions of semiconductor devices 300 as shown in FIGS. 3A, 3B, 3C, 3D and 3E. The doping conditions can be independently adjusted to improve segregation quality among adjacent well regions 20A and 20B as shown in FIGS. 3A, 3B, 3C, 3D and 3E.

FIG. 3F illustrates a doping profile of the semiconductor device as shown in FIG. 3A in accordance with some embodiments. FIG. 3G illustrates results of a simulation performed on the semiconductor device 300 as shown in e.g., FIG. 3A in accordance with some embodiments. As shown in FIGS. 3F and 3G, the semiconductor device 300, which includes both deep implant regions 40A and 40B as well as shallow implant regions 50A and 50B at both sides of the STI structure 30 in the substrate 10, has a smaller well-to-well spacing that is a distance between wells (e.g., about 0.5 to 1 μm), however has comparable and even lower well-to-well leakage current.

FIGS. 4A and 4B illustrate cross-sectional views of a semiconductor device 400 during various fabrication stages in accordance with some embodiments, in which two implant processes are performed after a forming of a STI trench 30′ in the substrate 10 and before a deposition of a dielectric material in the STI trench 30′.

As shown in FIG. 4A, a STI trench 30′ is formed in the semiconductor substrate 10 of a semiconductor device 400. Various methods of photolithography and etching can be used to form the STI trench 30′ in the substrate 10 of the semiconductor device 400. In some embodiments, a first well region 20A and a second well region 20B of dopant types opposite to each other are laterally formed at both sides of the STI trench 30′ in the substrate 10. Various methods of photolithography and implanting can be used to form the first well region 20A and the second well region 20B in the substrate 10.

Also as shown in FIG. 4A, in some embodiments, a first deep implant region 40A of a dopant type opposite to the dopant type of the adjacent first well region 20A is implanted via a hard mask 101 by an implanting, and the implanting partially passes through the STI trench 30′ that has not been deposited with a dielectric material yet, and thus may save implanting energy. The first deep implant region 40A is formed vertically lower than the STI trench 30′ and laterally between the first well region 20A and a lateral center C of the STI trench 30′ in the substrate 10.

Additionally, in some embodiments, a first shallow implant region 50A of a dopant type the same as the dopant type of the first deep implant region 40A is also implanted via the hard mask 101 by an implanting. The first shallow implant region 50A is formed vertically over the deep implant region 40A and laterally between the first well region 20A and the STI trench 30′.

After that, as shown in FIG. 4B, in some embodiments, a second deep implant region 40B of a dopant type opposite to the dopant type of the second well region 20B is implanted via another hard mask 102 by another implanting, and the other implanting partially passes through the STI trench 30′ and thus may save implanting energy. The second deep implant region 40B is formed vertically lower than the STI trench 30′ and laterally between the second well region 20B and the lateral center C of the STI trench 30′ in the substrate 10.

Additionally, in some embodiments, a second shallow implant region 50B of a dopant type the same as the dopant type of the second deep implant region 40B is also implanted via the hard mask 102 by an implanting. The second shallow implant region 50B is formed vertically over the deep implant region 40B and laterally between the second well region 20B and the STI trench 30′.

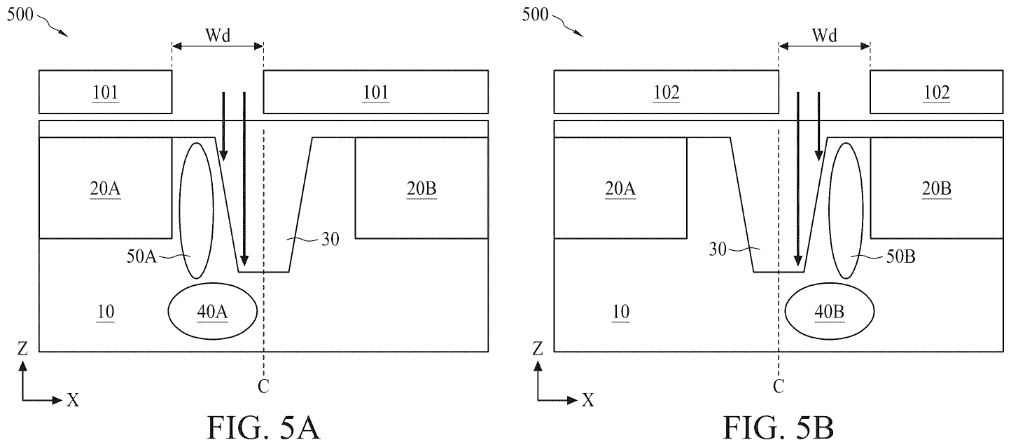

FIGS. 5A and 5B illustrate cross-sectional views of a semiconductor device 500 during various fabrication stages in accordance with other embodiments, in which two implant processes are performed after a deposition of a dielectric material in the STI trench 30′.

As shown in FIGS. 5A and 5B, a STI structure 30 is formed by filling or depositing a dielectric material in a STI trench (such as 30′ as shown in FIGS. 4A and 4B) in a substrate 10 of a semiconductor device 500. Various methods of photolithography and depositing can be used to form the STI structure 30 in the substrate 10 of the semiconductor device 500.

As shown in FIG. 5A, in some embodiments, a first deep implant region 40A of a dopant type opposite to the dopant type of the first well region 20A is implanted via a hard mask 101 by an implanting, and the implanting partially passes through the STI structure 30. The first deep implant region 40A is formed vertically lower than the STI structure 30 and laterally between the first well region 20A and a lateral center C of the STI structure 30 in the substrate 10 of the semiconductor device 500.

Additionally, in some embodiments, a first shallow implant region 50A of a dopant type the same as the dopant type of the first deep implant region 40A is also implanted by via the hard mask 101 by an implanting. The first shallow implant region 50A is formed vertically over the deep implant region 40A and laterally between the first well region 20A and the STI structure 30.

After that, as shown in FIG. 5B, a second deep implant region 40B of a dopant type opposite to the dopant type of the second well region 20B is implanted by another implanting via another hard mask 102, and the other implanting partially passes through the STI structure 30. The second deep implant region 40B is formed vertically lower than the STI structure 30 and laterally between the second well region 20B and the lateral center C of the STI structure 30 in the substrate 10.

Additionally, in some embodiments, a second shallow implant region 50B of a dopant type the same as the dopant type of the second deep implant region 40B is implanted via the hard mask 102 by an implanting. The second shallow implant region 50B is formed vertically over the deep implant region 40B and laterally between the second well region 20B and the STI structure 30.

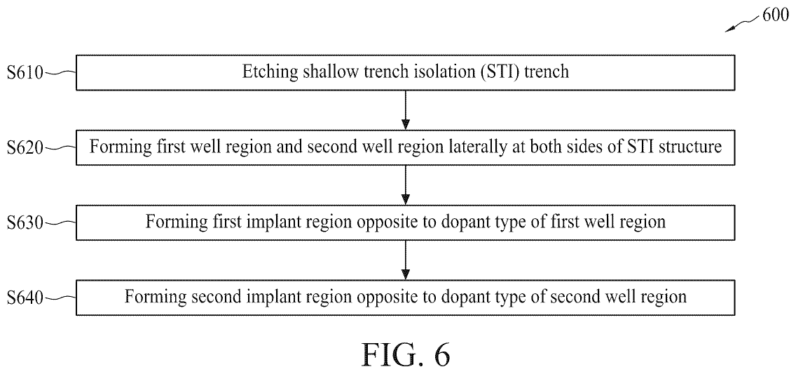

FIG. 6 is a flowchart illustrating a method 600 of manufacturing a semiconductor device as shown in FIG. 2A or FIG. 3A in accordance with some embodiments. It is understood that additional operations can be provided before, during, and after processes discussed in FIG. 6, and some of the operations described below can be replaced or eliminated, for additional embodiments of the method. The order of the operations/processes may be interchangeable and at least some of the operations or processes may be performed in a different sequence. In some embodiments, at least two or more operations or processes are performed overlapping in time, or almost simultaneously.

In operation S610, a shallow trench isolation (STI) trench 30′ (such as shown in FIGS. 4A and 4B) is formed in a semiconductor substrate 10. Various methods of photolithography and etching can be used to form the STI trench 30′ in a depth direction into the substrate 10 of the semiconductor device. In some embodiments, the STI trench 30′ is etched into the substrate 10 via a dry etching. In other embodiments, the STI trench 30′ is etched into the substrate 10 via a wet etching.

In some embodiments, a dielectric material is deposited in the STI trench 30′ to form a STI structure 30. Various methods of depositing can be used to fill the STI trench 30′ with a dielectric material to form a STI structure 30. In some embodiments, a dielectric material is deposited in the STI trench 30′ to form a STI structure 30 by chemical vapor deposition (CVD), or physical vapor deposition (PVD). In some embodiments, a high-density plasma chemical vapor deposition (HDP CVP) is used to deposit the dielectric material in a STI trench 30′ to form a STI structure 30. Trenches 30′ filled with the dielectric material may improve doping profile and concentration of the deep implant regions 40A and 40B.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is silicon wafer. The substrate 10 may include in its surface region, one or more buffer layers (not shown). The buffer layers can serve to gradually change the lattice constant from that of the substrate to that of the source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 10 includes silicon germanium (SiGe) buffer layers epitaxially grown on the silicon substrate 10.

In operation S620, a first well region 20A and a second well region 20B are laterally formed at both sides of the STI trench 30′ in the substrate 10. Various methods of photolithography and implanting can be used to form the first well region 20A and the second well region 20B in the substrate 10. In some embodiments, the dopant types of the first well region 20A and the second well region 20B are identical, as shown in FIGS. 2B and 2C. In other embodiments, the dopant types of the first well region 20A and the second well region 20B are opposite to each other, as shown in FIGS. 2D and 2E. In some embodiments, the STI trench 30′ surrounds any of the first well region 20A and the second well region 20B as shown in FIG. 1.

In operation S630, a first deep implant region 40A of a first dopant type opposite to a dopant type of the first well region 20A is implanted. The first deep implant region 40A is formed vertically lower than the STI trench 30′ and laterally between the first well region 20A and a lateral center C of the STI trench 30′ in the substrate 10 of the semiconductor device.

In operation S640, a second deep implant region 40B of a second dopant type opposite to a dopant type of the second well region 20B is implanted. The second deep implant region 40B is formed vertically lower than the STI trench 30′ and laterally between the second well region 20B and the lateral center C of the STI trench 30′ in the substrate 10 of the semiconductor device.

Various methods of photolithography and implanting can be used to form the first deep implant region 40A and the second deep implant region 40B at both sides of the STI trench 30′ in the substrate 10 of the semiconductor device. In some embodiments, the first deep implant region 40A and the second deep implant region 40B having identical dopant types can be formed by a single photolithography process and a single implanting process. In other embodiments, the first deep implant region 40A and the second deep implant region 40B having dopant types opposite to each other are formed by two photolithography processes and two implanting processes (such as shown in FIGS. 4A and 4B).

In some embodiments, a dielectric material is filled in the STI trench 30′ to form a STI structure 30 (such as shown in FIG. 2A) after the first implant region 40A and the second implant region 40B are formed.

In other embodiments, the dielectric material is filled in the STI trench 30′ to form a STI structure 30 (such as shown in FIG. 2A) before the first deep implant region 40A and the second deep implant region 40B are formed. In some embodiments, the dielectric material includes an isolation oxide.

In some embodiments, a first shallow implant region 50A of a dopant type identical to the dopant type of the first deep implant region 40A is implanted vertically over the first deep implant region 40A (as shown in FIG. 3A), and laterally between the first well region 20A and the STI structure 30 in the substrate 10 of the semiconductor device 300.

In some embodiments, a second shallow implant region 50B of a dopant type identical to the dopant type of the second deep implant region 40B is implanted vertically over the second deep implant region 40B (as shown in FIG. 3A), and laterally between the second well region 20B and the STI structure 30 in the substrate 10 of the semiconductor device 300.

In some embodiments, a dopant concentration in the first deep implant region 40A is higher than a dopant concentration in the first shallow implant region 50A, and a dopant concentration in the second deep implant region 40B is higher than a dopant concentration in the second shallow implant region 50B.

In the present disclosure, two deep implant regions having dopant types opposite to dopant types of two adjacent implant well regions are deposited at both sides of and lower than a STI structure can improve segregation between the two adjacent implanted wells, and thus advantageously minimize well-to-well leakage current, thereby leading to more compact chip design and more robust chip performance.

In one aspect of the present disclosure, a semiconductor device is disclosed. The semiconductor device includes a first well region laterally separated from a second well region in a substrate; a shallow trench isolation (STI) structure laterally between the first well region and the second well region in the substrate; a first implant region of a dopant type opposite to a dopant type of the first well region in the substrate, disposed vertically lower than the STI structure and laterally between the first well region and a lateral center of the STI structure; and a second implant region of a dopant type opposite to a dopant type of the second well region in the substrate, disposed vertically lower than the STI structure and laterally between the second well region and the lateral center of the STI structure.

In another aspect of the present disclosure, a semiconductor device is disclosed. The semiconductor device includes a first well region laterally separated from a second well region in a substrate; a shallow trench isolation (STI) structure laterally between the first well region and the second well region in the substrate; a first deep implant region of a first dopant type opposite to a dopant type of the first well region, vertically lower than the STI structure, and laterally between the first well region and a lateral center of the STI structure; a second deep implant region of a second dopant type opposite to a dopant type of the second well region, vertically lower than the STI structure, and laterally between the second well region and the lateral center of the STI structure; a first shallow implant region of the first dopant type, vertically over the first deep implant region, and laterally between the first well region and the STI structure; and a second shallow implant region of the second dopant type, vertically over the second deep implant region, and laterally between the second well region and the STI structure.

In yet another aspect of the present disclosure, a method for fabricating semiconductor devices is disclosed. The method includes etching a shallow trench isolation (STI) trench in the substrate; forming a first well region and a second well region laterally at both sides of the STI structure in a substrate; forming a first implant region of a first dopant type opposite to a dopant type of the first well region, vertically lower than the STI trench, and laterally between the first well region and a lateral center of the STI trench in the substrate; and forming a second implant region of a second dopant type opposite to a dopant type of the second well region, vertically lower than the STI trench, and laterally between the second well region and a lateral center of the STI trench in the substrate.

As used herein, the terms “about” and “approximately” generally indicate the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an isolation structure formed along a substrate of the semiconductor device, the isolation structure configured to physically separate a first well region of a first dopant type from a second well region of a second dopant type both formed along the substrate of the semiconductor device; and
a dielectric material occupying a cavity defined by the isolation structure, the dielectric material configured to electrically isolate the first well region from the second well region.

2. The semiconductor device of claim 1, further comprising:
a first implant region of a third dopant type opposite to the first dopant type of the first well region in the substrate, and disposed vertically lower than the isolation structure; and
a second implant region of a fourth dopant type opposite to the second dopant type of the second well region in the substrate, and disposed vertically lower than the isolation structure.

3. The semiconductor device of claim 2, further comprising:
a third implant region of the third dopant type in the substrate, disposed over the first implant region and laterally between the first well region and the isolation structure; and
a fourth implant region of the fourth dopant type in the substrate, disposed over the second implant region and laterally between the second well region and the isolation structure.

4. The semiconductor device of claim 3, wherein a first dopant concentration in the first implant region is higher than a third dopant concentration in the third implant region, and wherein a second dopant concentration in the second implant region is higher than a fourth dopant concentration in the fourth implant region.

5. The semiconductor device of claim 2, wherein the isolation structure surrounds each of the first well region and the second well region, wherein the first implant region is disposed laterally between the first well region and a lateral center of the isolation structure, and wherein the second implant region is disposed laterally between the second well region and the lateral center of the isolation structure.

6. The semiconductor device of claim 2, wherein a ratio of a width of the first implant region to a width of the isolation structure is in a range from 5/100 to 95/100, and wherein a ratio of a width of the second implant region to the width of the isolation structure is in a range from 5/100 to 95/100.

7. The semiconductor device of claim 1, further comprising a first complementary metal-oxide-semiconductor (CMOS) device formed in the first well region and a second CMOS device formed in the second well region, wherein the first CMOS device comprises a first planar MOSFET transistor, and wherein the second CMOS device comprises a second planar MOSFET transistor.

8. The semiconductor device of claim 1, wherein the first dopant type and the second dopant type are identical.

9. The semiconductor device of claim 1, wherein the first dopant type and the second dopant type are opposite.

10. A semiconductor device, comprising:
a first well region of a first dopant type and a second well region of a second dopant type formed along a substrate of the semiconductor device
an isolation structure formed along the substrate of the semiconductor device laterally separating the first well region from the second well region; and
an isolation oxide occupying a cavity defined by the isolation structure, the isolation oxide configured to electrically isolate the first well region from the second well region.

11. The semiconductor device of claim 10, further comprising:
a first deep implant region of a first dopant type opposite to a dopant type of the first well region, and vertically lower than the isolation structure;
a second deep implant region of a second dopant type opposite to a dopant type of the second well region, and vertically lower than the isolation structure;
a first shallow implant region of the first dopant type, vertically over the first deep implant region, and laterally between the first well region and the isolation structure; and
a second shallow implant region of the second dopant type, vertically over the second deep implant region, and laterally between the second well region and the isolation structure.

12. The semiconductor device of claim 11, wherein a dopant concentration in the first deep implant region is higher than a dopant concentration in the first shallow implant region, and wherein a dopant concentration in the second deep implant region is higher than a dopant concentration in the second shallow implant region.

13. The semiconductor device of claim 11, wherein the first dopant type of the first deep implant region and the second dopant type of the second deep implant region are opposite to each other.

14. The semiconductor device of claim 11, wherein the first dopant type of the first deep implant region and the second dopant type of the second deep implant region are identical.

15. The semiconductor device of claim 10, wherein the isolation structure surrounds each of the first well region and the second well region.

16. The semiconductor device of claim 10, further comprising a first planar CMOS device in the first well region and a second planar CMOS device in the second well region.

17. A semiconductor device, comprising:
a first well region of a first dopant type and a second well region of a second dopant type formed along a first lateral axis of the semiconductor device
an isolation structure formed along the first lateral axis of the semiconductor device separating the first well region from the second well region along a second lateral axis perpendicular to the first lateral axis; and
a dielectric material occupying a cavity defined by the isolation structure, the isolation material configured to electrically isolate the first well region from the second well region.

18. The semiconductor device of claim 17, wherein the isolation structure extends farther along the second lateral axis than the first well region and the second well region.

19. The semiconductor device of claim 17, further comprising:
a first implant region of a third dopant type opposite to the first dopant type of the first well region, and disposed lower along the first lateral axis than the isolation structure;
a second implant region of a fourth dopant type opposite to the second dopant type of the second well region, and disposed lower along the first lateral axis than the isolation structure;
a third implant region of the third dopant type, disposed over the first implant region and laterally along the second lateral axis between the first well region and the isolation structure; and
a fourth implant region of the fourth dopant type, disposed over the second implant region and laterally along the second lateral axis between the second well region and the isolation structure.

20. The semiconductor device of claim 19, wherein the isolation structure surrounds each of the first well region and the second well region, wherein the first implant region is disposed laterally along the second lateral axis between the first well region and a lateral center of the isolation structure, and wherein the second implant region is disposed laterally along the second lateral axis between the second well region and the lateral center of the isolation structure.
